(19) United States
(12) Patent Application Publication
(10) Pub. No.: US 2026/0038543 A1
(43) Pub. Date: Feb. 5, 2026

(54) THREE-DIMENSIONAL MEMORY STRUCTURES, AND RELATED METHODS OF OPERATION AND CONSTRUCTION

(71) Applicant: Micron Technology, Inc., Boise, ID (US)

(72) Inventors: Nirav Vora, Meridian, ID (US); Zhao Zhao, Meridian, ID (US)

(21) Appl. No.: 19/276,420

(22) Filed: Jul. 22, 2025

Related U.S. Application Data
(60) Provisional application No. 63/677,850, filed on Jul. 31, 2024.

(51) Int. Cl. G11C 5/06; H01L 21/768; H10B 63/00; H10N 70/00

(52) U.S. Cl. CPC G11C 5/063; H01L 21/76843; H10B 63/84; H10N 70/021; H10N 70/841; H10N 70/883

(57) ABSTRACT

Memory devices, such as three-dimensional cross-point memory devices, and methods of manufacturing such devices are addressed. Multiple methods of manufacturing such memory devices are described to provide improved protection of replacement gate structures, such as word lines and word line liners. These include multiple processing flows which forming one or more additional barrier structures between structures subject to at least partial removal during the processing flow; wherein some portion of the additional barrier structure(s) will remain at the end of manufacturing.

### PRIORITY APPLICATION

This application claims the benefit of priority to U.S. Provisional Application Ser. No. 63/677,850, filed Jul. 31, 2024, which is incorporated herein by reference in its entirety.

### BACKGROUND

Memory structures are semiconductor circuits that provide electronic storage of data for an associated “host” system (e.g., a processor or other logic circuitry, a computer, or other electronic device). Memory structures may be formed integral to an associated host system, or portion thereof, or may be formed independently as memory devices. Memory structures may be formed as either volatile or non-volatile memory. Of these, volatile memory requires power to maintain data, and includes devices such as, static random-access memory (SRAM), dynamic random-access memory (DRAM), or synchronous dynamic random-access memory (SDRAM), among others. Non-volatile memory can retain stored data when not powered, and includes devices such as flash memory, electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

As the needs for have increased for memory providing larger storage capacities, and at the same time increased storage efficiency (storage capacity per spatial area), memory structures having multiple layers of memory cells forming a three-dimensional (“3D”) array of memory cells (also termed herein a “memory array”) have become increasingly common. Various forms of memory, including, for example, both non-volatile memory, such as flash, and volatile memory, such as DRAM, have been implemented as 3D memory structures.

Another configuration of memory, however, known generally as crosspoint-memory structures, have become desirable due to potentially relatively simpler manufacturing and greater storage efficiency. For avoidance of doubt, the referenced crosspoint-memory structures, are not to be confused with “X-point*” memory, which is a registered trademark of Intel corporation associated with a specific cross-point memory technology.

Crosspoint-memory includes an array of multiple word lines extending generally within multiple first planes, the word lines typically extending generally parallel to one another in a first direction, and an array of multiple bit lines extending generally within multiple second planes, the multiple bit lines generally intersecting with the first planes of word lines (and in most cases extending generally orthogonal to the first planes of word lines). Proximate the general intersection of a word line with a bit line, there may typically be a discrete programmable element having a variable property associated with an electrical state which, in a single bit memory cell is indicative of a 1 or 0, or in a multiple bit memory cell is indicative of one of more than two electrical states, indicating one of multiple possible bits.

Always increasing demands for greater memory capacity and improved speed, as well as reliability during the manufacturing process and in the finished device.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 depicts a schematic of an example configuration for a planar crosspoint-memory array.

FIGS. 2A-2C depicts layout representations of cross-point memory arrays, in which FIG. 2A depicts an example memory array from a top view; while FIGS. 2B-2C depicts the example memory array from common side views.

FIGS. 3A-3B depict a multi-tier structure of an example structure suitable for use in forming a three-dimensional cross-point memory array; depicted in FIG. 3A from a side view, and depicted in FIG. 3B from a top view, and after initial processing.

FIGS. 4A-4I depict successive representative stages of an example process flow for forming structures of a memory array in accordance with the present disclosure, in which each figure, with the exception of FIG. 4D, depicts the example stage from both a top view and a lateral view; wherein the top view depicts a region spanning three pillars of the memory array; and wherein the side view spans a region spanning two pillars of the three pillars of the top view.

FIGS. 5A-5B depict representative stages of an alternative process flow for forming structures of a memory array in accordance with the present disclosure.

FIGS. 6A-6B depict representative stages of another alternative process flow for forming structures of a memory array in accordance with the present disclosure.

FIGS. 7A-7I depict representative stages of yet another alternative process flow for forming structures of a memory array in accordance with the present disclosure.

FIG. 8 depicts a flowchart of an example method for forming structures of the memory array in accordance with the present disclosure.

FIG. 9 depicts a block diagram representation of an example electronic system that may incorporate one or more memory arrays constructed in accordance with the present disclosure.

### DETAILED DESCRIPTION

This specification addresses multiple memory structures which may be implemented in discrete memory devices (individually packaged, or packaged as a multichip device), or in one or more memory arrays implemented on a wafer (or portion thereof) comprising, for example, non-memory related structures and circuitry. Unless indicated otherwise by context, the terms “memory structures” and “memory devices” are used interchangeably with respect to the described structures, wherever the structures may be implemented.

In 3D memory structures, as noted above, memory cells are typically located in different levels, for example memory layers or tiers. These memory layers or tiers are separated from one another by separation layers or tiers, which in many examples are formed of primarily of one or more dielectric materials, which facilitates the memory cells being formed in contact with the dielectric separation layers or tiers, which for intermediate memory tiers sandwich the memory cell tiers.

In the described cross-point memory devices, each memory cell includes a configurable memory element which may be programmed to one of multiple physical states associated with a respective electrical property, and therefore associated with a data state. For purposes of the present example, the described configurable memory elements are variable resistance memory elements in which different resistance states of the memory cell represent respective data states. For purposes of the present examples, the variable resistance memory cells are described as including a chalcogenide configurable memory element. As known to persons skilled in the art, chalcogenides are combinations or alloys of certain materials, commonly including combinations of two or more of selenium (Se), tellurium (Te), arsenic (As), antimony (Sb), carbon C, germanium (Ge), silicon (Si), and/or indium (In). In some examples, chalcogenide material by include additional elements such as one or more of hydrogen (H), oxygen (O), nitrogen (N), chlorine (CI), or fluorine (F), in either atomic or molecular form.

As is known to persons skilled in the art, chalcogenide elements are known for use in phase change memory elements, in which a physical phase change may be induced in the chalcogenide element. For example, chalcogenide-containing elements may change between a relatively amorphous-disordered-state, and a relatively crystalline-ordered-state. In some examples, these physical phase states may be characterized by different resistive properties, such that measurement of the resistance across the Chalcogenide elements identifies the data state associated with the physical state of each phase change memory element. In some examples, properties of the Chalcogenide-containing storage element other than electrical resistance may be measured to identify one or more data states associated with the physical state of each phase change memory element.

One desirable technique for forming such cross-point memory structures is that generally termed as a “replacement gate” method, in which a placeholder material is used during initial processing of a stacked memory structure for ease of processing to form initial structures; and then the placeholder material is selectively removed, and replaced, at least in part, by metal or metal alloy structures, such as to form, for example word lines and other conductive structures.

Though such processing provides substantial advantages during manufacture, subsequent manufacturing steps can still expose the replacement metal, and metal liner materials to chemistries which will attack either or both types of material, and which can lead to an increase for example, in word line resistance, or word line failure. Such increased resistance, when present, is detrimental to the functioning of the completed memory structure.

Accordingly, the present disclosure addresses multiple methods of forming a cross-point memory structure which provide improved protection of replacement metal structures, such as word lines and word line liners, during the manufacturing process. Described herein are multiple processing flows which include example ways of forming one or more additional barrier structures between one or more structures subject to at least partial removal during the processing flow, and wherein some portion of the additional barrier structure(s) will remain at the end of processing. In some examples, portions of the additional barrier structure may remain at locations proximate the word line barrier material (i.e., at a location either contacting the word line barrier material or separated from the word line barrier material by a single layer of one other material). Such methods, and the resulting memory structures, are believed to both improve the manufacturing process, and potentially the yield of suitable devices resulting from such processes; as well as improving the electrical integrity and performance of the completed memory structures.

In the following discussion, various structures and features of the drawings are indicated by respective reference numerals. In some cases, structures being referred to in later figures may be essentially the same as, or directly comparable to, structures discussed relative to prior figures. In such circumstances, for clarity of description, the reference numerals from the earlier figures will be used in the subsequent drawings.

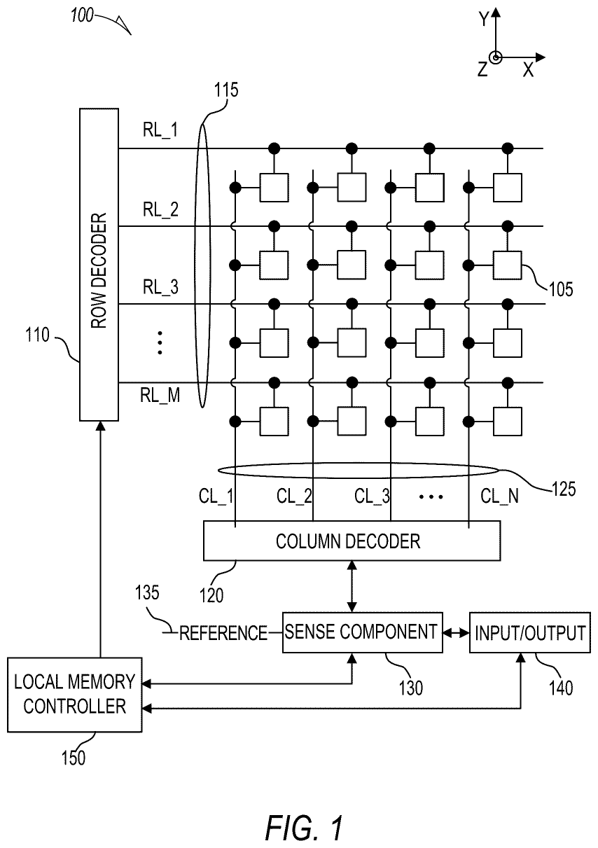

FIG. 1 depicts an example configuration of a memory structure 100 including a planar crosspoint-memory array 102, memory structure 100 includes a local memory controller 150, along with the decoding and sensing circuitry used in operating memory structure 100. Such a memory structure 100 may be implemented in a discrete memory die (or “memory chip”, as may be individually packaged, or as may be combined with other die (potentially including other memory die and/or other semiconductor die or interface devices); and may form a part of a larger microelectronic device (i.e., a computer, phone, controller, etc.). Alternatively, the memory structure 100 may be one of multiple structures formed on an individual semiconductor die or wafer, such as, in one example, cache memory formed on a semiconductor die also containing one or more processor cores, or other logic structures. In the context of the present specification, each of these example memory structures, however implemented, constitutes a “memory device.”

Memory structure 100 contains multiple memory cells 105 coupled between a respective row line (RL-1, RL-2 . . . . RL-M), and a respective column line (CL-1, CL-2 . . . . CL-M). The memory cells 105 are configured to be programmable to store one of multiple logic states. In a single bit memory cell, a memory cell will be programmed to one of two possible logic states (0 or 1) to store a single bit of data. Though, as described earlier herein, in another example, in which memory cells 105 are implemented as multiple bit memory cells, each memory cell 105 will be implemented to store more than one bit of information at a time through additional logic states (00, 01, 10, 11, for example).

Memory cells 105 store the logic states through use of a configurable material within the cell (also referred to as a “memory element” or “storage element”), which is configurable to one of multiple states, each state associated with a respective logic state. For purposes of the present example, the configurable material/memory element within each of memory cells 105 may include a chalcogenide alloy as discussed above, to form a phase change memory cell. For purposes of the present examples, such a phase change memory cell may be placed in one of multiple possible phase states, each phase state associated with a logic state, as described above. For purposes of the present example, each phase state may be determined by an electrical measurement, for example, a resistivity measurement of the memory element, to identify the phase state, and thus the logic state. In some examples, a logic 0 may be indicated by the memory element in a RESET state (for example, a relatively amorphous, disordered state), and a logic 1 may be indicated by the memory in a SET state (for example, a relatively crystalline, ordered state). In some systems, additional phase states may be achievable, and may be used to identify one or more additional logic states. Additionally, other properties may be measured in place of resistivity, to determine a logic phase state of the memory element.

The memory array 102 may include access lines (including, here, e.g., row lines 115 each extending along an illustrative x-direction; column lines 125 each extending along an illustrative y-direction arranged in a pattern, such as a grid-like pattern. Access lines may be formed with one or more conductive materials. In some examples, row lines 115 (RL_1, RL_2 to RL_M, etc.), or some portion thereof, may be referred to as word lines. In some examples, column lines 125 (CL-1, CL_2 to CL_N, etc.), or some portion thereof, may be referred to as digit lines or bit lines. Such word lines extend in first planes, and in a first direction, and each word line extends to respective first pluralities of memory cells in a respective memory tier; while the bit lines extend within second planes and in a second direction and extends to respective second pluralities of memory cells distributed across multiple memory tiers, such that each word line extends proximate multiple bit lines, and that each bit line extends proximate multiple word lines.

Memory cells 105 may be positioned at proximity intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory structure 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and/or a column line 125 (e.g., applying a voltage to the row line 115 or the column line 125), a memory cell 105 may be accessed in accordance with their proximity intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory structure 100 may perform operations responsive to commands, which may be issued by a host device coupled with the memory structure 100 or may be generated by the memory structure 100 (e.g., by a local memory controller 150).

During a write operation (e.g., a programming operation) of a self-selecting or thresholding memory cell 105, a polarity used for a write operation may influence (e.g., determine, set, or program) a behavior or characteristic of the material of the memory cell 105, such as a thresholding characteristic (e.g., a threshold voltage) of the material. A difference between thresholding characteristics of the material of the memory cell 105 for different logic states stored by the material of the memory cell 105 (e.g., a difference between threshold voltages when the material is storing a logic state ‘0’ versus a logic state ‘1’) may correspond to a read window of the memory cell 105).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory structure 100 or to a host device coupled with the memory structure 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory structure 100), translate the information into a signaling that can be used by the memory structure 100, perform one or more operations on the memory cells 105 and communicate data from the memory structure 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory structure 100. In general, the amplitude, the shape, or the duration of an applied signal discussed herein may be varied and may be different for the various operations discussed in operating the memory structure 100.

The local memory controller 150 may be operable to perform one or more access operations on one or more memory cells 105 of the memory structure 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory structure 100 that are not directly related to accessing the memory cells 105.

As discussed above, in some examples, example memory structure 100 may include a memory array 102 of memory cells 105 arranged in a three-dimensional architecture that includes memory cells 105 arranged according to different levels (e.g., layers, decks, tiers). For example, vertically offset levels of memory cells 105 may be separated by intervening levels of dielectric materials such that the memory cells 105 are formed in contact with the dielectric material levels.

The memory structure 100 may include any quantity of non-transitory computer-readable media that support memory cell protective layers in a three-dimensional memory array. For example, a local memory controller 150, a row decoder 110, a column decoder 120, a sense component 130, or an input/output component 140, or any combination thereof may include or may access one or more non-transitory computer-readable media storing instructions (e.g., firmware) for performing the functions ascribed herein to the memory structure 100. For example, such instructions, if executed by the memory structure 100, may cause the memory structure 100 to perform one or more associated functions as described herein.

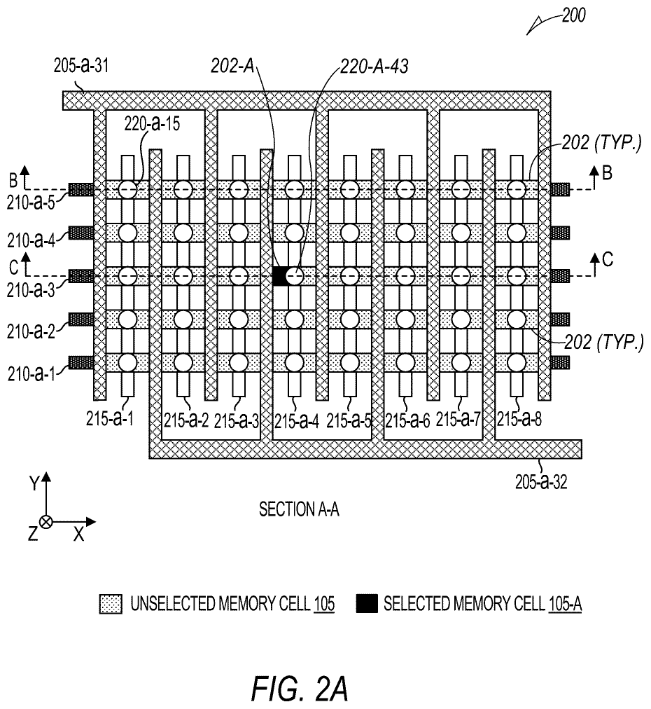

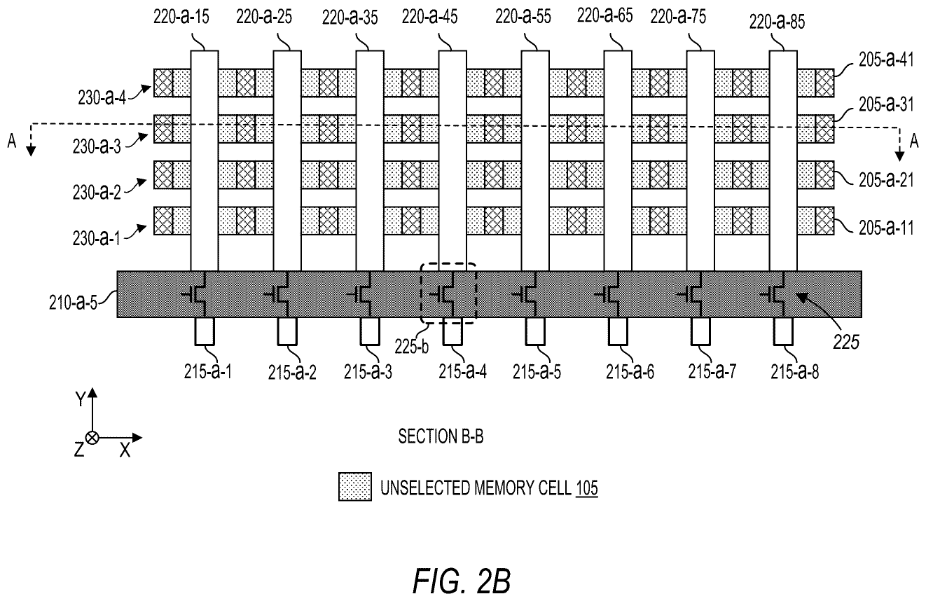

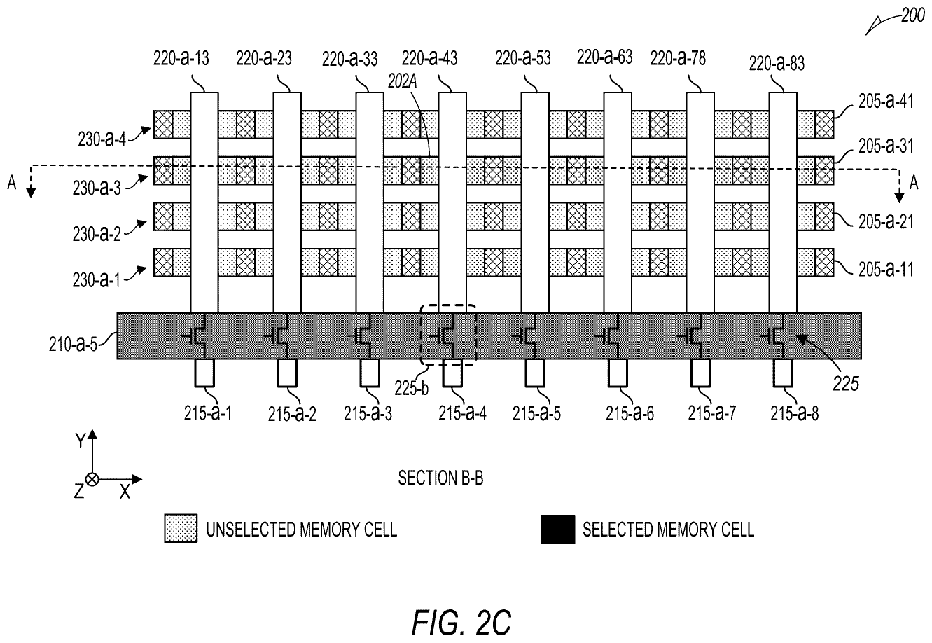

Referring now to FIGS. 2A-2C, the figures depict an example memory array 200 that supports memory cell layers in a three-dimensional memory array in accordance with examples as disclosed herein. The memory array 200 may be included in a memory structure 100, and illustrates an example of a three-dimensional arrangement of cross-point memory cells 202 that may be accessed by various conductive structures (e.g., access lines). FIG. 2A depicts a top section view (e.g., Section A-A) of the memory array 200 relative to a cut plane A-A as shown in FIGS. 2B and 2C. FIG. 2B illustrates a side section view (e.g., Section B-B) of the memory array 200 relative to a cut plane B-B as shown in FIG. 2. FIG. 2C illustrates a side section view (e.g., Section C-C) of the memory array 200 relative to a cut plane C-C as shown in FIG. 2. The section views provide hope and examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2A, 2B, and 2C. Although some elements included in FIGS. 2A, 2B, and 2C are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 202 and word lines 205 may be distributed along the z-direction according to levels 230 (e.g., layers, planes, tiers, as illustrated in FIGS. 2B and 2C). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels, and greater) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 202 on a first side (e.g., along the x-direction) of a given pillar 220 and an even word line (e.g., of the same level 230) may be associated with a second memory cell 202 on a second side (e.g., along the x-direction, opposite the first memory cell 202) of the given pillar 220. Thus, in some examples, memory cells 202 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an x-y plane) having a first quantity of pillars 220 along a first direction (e.g., eight pillars along the x-direction, eight rows of pillars), and having a second quantity of pillars 220 along a second direction (e.g., five pillars along the y direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 202 (e.g., along the z-direction, one or more will memory cells 202 for each level 230). A pillar 220 that extends along the z-direction may have a cross-sectional area in an x-y plane. Although illustrated with a circular cross-sectional area in the x-y plane, a pillar 220 may be formed with a different shape, such as having an elliptical, square, rectangular, polygonal, or other cross-sectional area in an x-y plane.

The memory cells 202 each may include a chalcogenide material. In some examples, the memory cells 202 may be examples of thresholding memory cells. Each memory cell 202 may be accessed (e.g., addressed, selected) according to a proximate intersection between a word line 205 (e.g., a level selection, which may include an even or odd selection within a level 230) and a pillar 220 at the memory element. For example, as illustrated, a selected memory cell 202-a of the level 230-a-3 may be accessed according to such a proximate intersection between the pillar 220-a-43 and the word line 205-a-32.

A memory cell 202 may be accessed (e.g., written to, read from) by applying an access bias (e.g., an access voltage, Vaccess, which may be a positive voltage or a negative voltage) across the memory cell 202. In some examples, an access bias may be applied by biasing a selected word line 205 with a first voltage (e.g., Vaccess/2) and by biasing a selected pillar 220 with a second voltage (e.g., −Vaccess/2), which may have an opposite sign relative to the first voltage. Regarding the selected memory cell 202-a, a corresponding access bias (e.g., the first voltage) may be applied to the word line 205-a-32, while other unselected word lines 205 may be grounded (e.g., biased to OV). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −Vaccess/2) to the pillar 220-a-43, the sense line 215-a-4 may be biased with the access bias, and the gate line 210-a-3 may be grounded (e.g., biased to OV) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 2B, may be biased with a voltage equal to or similar to an access bias (e.g., −Vaccess/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 202 may be written to by applying a write bias (e.g., where Vaccess=Vwrite, which may be a positive voltage or a negative voltage) across the memory cell 202. In some examples, a polarity of a write bias may influence (e.g., determine, set, program) a behavior or characteristic of the material of the memory cell 202, such as the threshold voltage of the material. For example, applying a write bias with a first polarity may set the material of the memory cell 202 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 202 for different logic states stored by the material of the memory cell 202 (e.g., a difference between threshold voltages when the material is storing a logic state ‘0’ versus a logic state ‘1’) may correspond to the read window of the memory cell 202.

In a read operation, a memory cell 202 may be read from by applying a read bias (e.g., where Vaccess=Vread, which may be a positive voltage or a negative voltage) across the memory cell 202. In some examples, a logic state of the memory cell 202 may be evaluated based on whether the memory cell 202 thresholds in the presence of the applied read bias. For example, such a read bias may cause a memory cell 202 storing a first logic state (e.g., a logic 0) to threshold (e.g., permit a current flow, permit a current above a threshold current), and may not cause a memory cell 202 storing a second logic state (e.g., a logic 1) to threshold (e.g., may not permit a current flow, may permit a current below a threshold current).

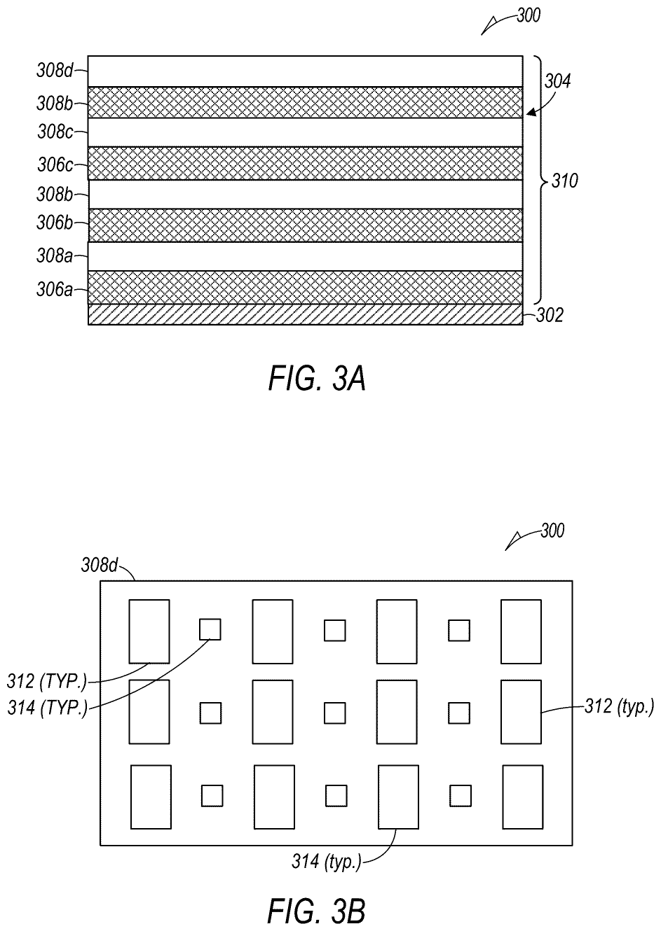

FIGS. 3A-3B depicts an example multi-tier memory structure 300 which may be formed and used as an initial structure from which the example structures of the remaining figures are formed. Multi-tier memory structure 300 is formed on a substrate 302, which in many cases will be a semiconductor substrate, for example a silicon substrate. Though in some examples, substrate 302 may be formed of another material, for example a glass or ceramic material, which supports either directly or indirectly (through intervening materials) the multi-tier memory structure. Multi-tier memory structure 300 includes an alternating stack structure forming the memory array portion 304 of the memory structure (after later processing), as described herein).

Structures used in forming the memory array portion 304 of memory structure 300 may be formed directly on the substrate 302 or above one or more levels of material extending over a surface of the substrate (not depicted). The memory array portion 304 (also termed herein, “memory array”), includes a stacked tier structure 310 which includes a stack of multiple alternating tiers of different material compositions. In many cases, a first set of dielectric tiers 306 (identified as 306a-306d) will include a first dielectric material to facilitate forming conductive structures alternating in between the dielectric tiers 306; as such the dielectric tiers may also be considered as spacer or separation tiers. In many examples the dielectric tiers 306 of the alternating tiers will comprise one or more oxides. Alternating with the dielectric tiers are the second set of tiers 308, termed herein “memory tiers,” as further described below. In the present example, these memory tiers 308 will initially include a placeholder material which may be selectively removed relative to the material of the first set of dielectric tiers 306.

For purposes of the present examples, construction of the memory array portion 304 will be accomplished through use of a technique broadly described as a “replacement gate” processing, in which various structures of the memory array will be constructed with the initial material of the second set of tiers 308 being a placeholder material. And at a later stage of processing, that placeholder material will be removed, at least in part, and replaced with a replacement gate material, commonly a metal or metal alloy, a significant portion of which will form word lines of the memory array. The memory tiers 308 will ultimately contain other materials forming bodies of memory cells, and thus for purposes of this illustration, for a convenient term to provide clarity of explanation, the second set of alternating tiers 308 between the tiers of dielectric material are termed in the present description “memory tiers,” addressing the location and ultimate function of the tier, regardless of whether that location is occupied by the initial placeholder material or by the later-placed replacement gate material.

The dielectric tiers 306 facilitate the memory cells being formed in contact with the dielectric tiers 306, which for intermediate memory tiers sandwich the memory tiers. For purposes of the present example, the dielectric tiers 306 will be described as formed of oxide. And in such examples, the initial placeholder material of the memory tiers 308 may commonly be a nitride of a composition selectively removable relative to the selected oxide of the tiers 306.

In the present examples, only a limited number of vertically alternating dielectric tiers 306 and memory tiers 308 are depicted, for clarity. Persons skilled in the art will recognize that a much greater number of such alternating tiers will typically be present in a commercial memory structure. For example, in various types of 3D memory structures, hundreds of memory tiers 308, and accompanying dielectric tiers 306, may be present. As persons skilled in the art will recognize, in some examples, memory tiers may be formed in vertically arranged groups (commonly termed “decks”) which interconnect to form the memory array.

Once the stacked tier structure 310 has been formed to a desired number of alternating memory tiers and dielectric tiers (as in FIG. 3), openings will be formed in the tiers for forming, and for accommodating, other structures of the memory array. In the depicted example, multiple pier openings 312 have been formed extending through at least a portion of the stacked tier structure 310; and multiple pillar openings 314 have been formed extending through a respective portion of the stacked tier structure (which may in some examples be the same portion is that through which the pier openings 312 extend).

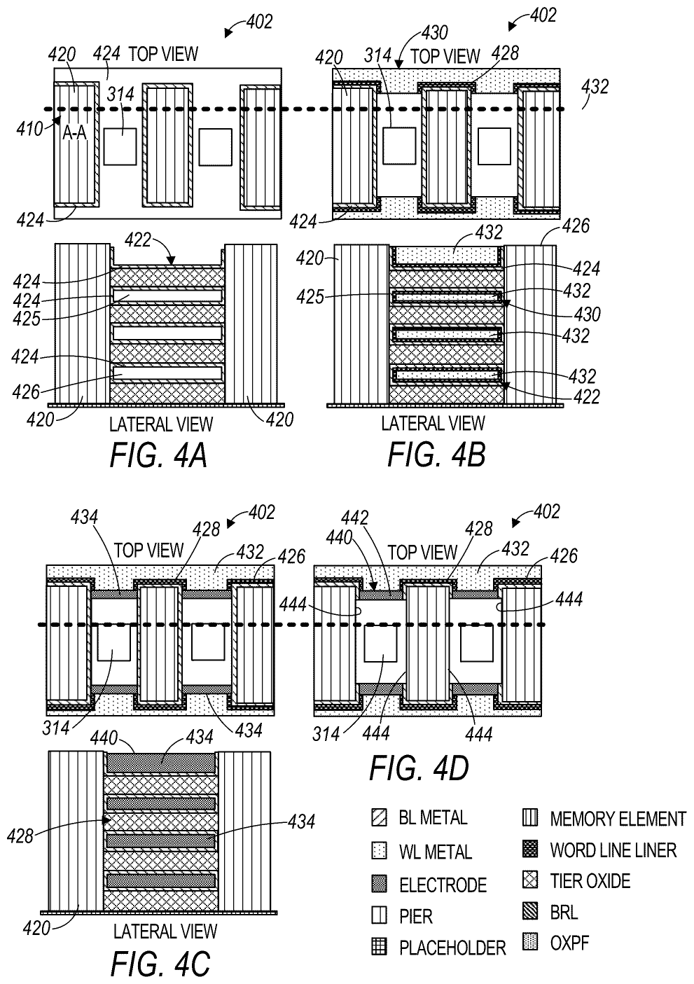

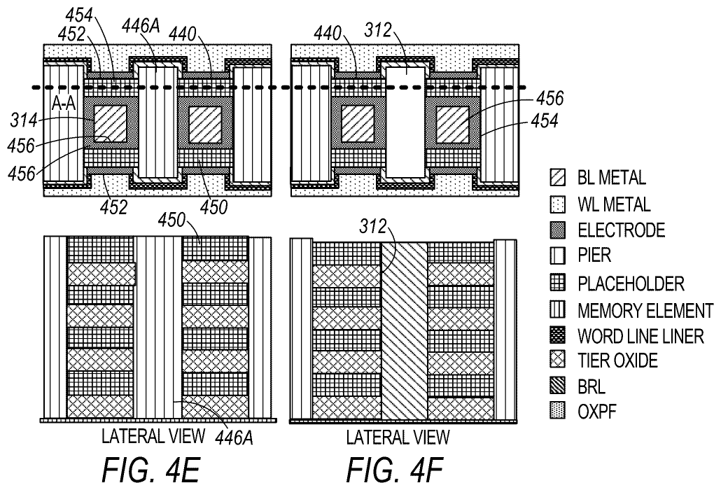

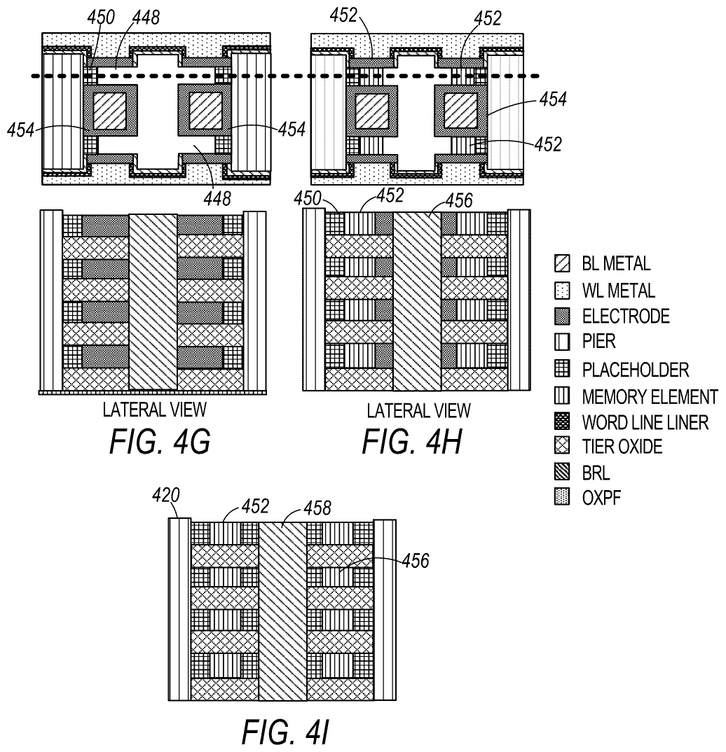

FIGS. 4A-4I depict example stages in an example process flow 400 for forming an example three-dimensional (“3D”) memory array, indicated generally at 402, through depiction of a portion of a memory array (such as example array 200 of FIGS. 2A-2C) at various representative stages of an example manufacturing process flow. The stages of these Figures follow from the stacked tier structure 310 of FIG. 3A. The representative stages of each figure include two portions, an upper plan view of a representative memory tier, indicated generally at 404, and lower plan view of a representative dielectric tier, indicated generally at 406, as will be vertically adjacent to at least one respective memory tier 404. For avoidance of doubt, the various stages of the process flow are represented by formation of memory cell structures to each side of a central pier, and extending to adjacent piers to each side of the central pier. Although not depicted in the representative stages, it should be understood that the same type of memory cell structures is also being formed on both sides of all piers aligned along the word line direction; and thus, the same memory cell structures are being constructed beyond the outermost piers in the depiction of each stage. As depicted in FIG. 3A the initial stacked tier structure includes an alternating series of pier openings and pillar openings, and the pattern of memory cell formation similarly repeats along the word line direction.

For the avoidance of doubt, the term “adjacent” is used herein to identify structures or materials which are near to one another (within the dimensional scale of dimensions of structures, thickness of material layers, etc.), though not necessarily in physical contact with one another (as they may be separated by a material layer, for example). In the case of repeating structures that will be described, such as piers and pillars, which are in spaced relation to one another throughout the memory array, the term “adjacent” is used to identify that the two structures (piers, for example) are the neighboring structures (i.e., two piers are “adjacent” to one another along a first access, when there is no other pier along the first axis between the two piers along the first axis).

As depicted in FIG. 4A, relative to stacked tier structure 310 of FIGS. 3A-B, the pier openings 312 have been filled with a suitable pier fill material 410 to form piers 420 in contact with the stacked structure surfaces defining pier openings 312. For example, for purposes of the present example, the pier fill material 410 may be ion-doped silicon nitride, or other dielectrics which can be selectively etched relative to the material of dielectric tiers 306 and silicon nitride, as the initial placeholder material of the memory tiers. In certain examples, the pier fill material 410 may be the same for all piers; however, in other examples, a first group of piers may have a first fill material such as that described above; while selected piers may have a different fill material, for example in response to placement of the selected piers proximate structures of the memory array to be formed later, and which cases the different fill material may be selected to facilitate later processing, potentially involving only the selected piers.

Additionally, pillar openings 314 will ultimately contain respective conductive pillars serving as portions of bit lines of the memory array 402. As a result, in many examples, pillar openings 314 may commonly extend to intersect a respective conductive material structure formed above the substrate, but beneath the stacked tier structure, and forming a portion of respective memory array bitlines.

FIG. 4A further reflects additional processing, including exhuming the original placeholder material in the memory tiers 308 through use of the pillar openings 314, to facilitate forming the replacement gates/wordlines of the memory array. As identified previously, the placeholder material 412 in the memory tiers 308 may be a nitride, in which case the nitride is exhumed, opening voids between the remaining structures and exposing surfaces of remaining structures. For example, surfaces of piers 420 between dielectric tiers 306 are exposed, while leaving the dielectric tiers, and the supporting piers intact (with the exception of the previously formed pillar openings 314 extending through the dielectric tiers 306 of the stacked structure, which exist outside of the plane of the vertical section of FIG. 4A).

Subsequent to exposing the piers 420 and dielectric tiers 306, a conformal barrier material 422 is deposited through the pillar openings onto the exposed surfaces of the dielectric tiers and piers. This conformal barrier material 422 defines openings between dielectric tiers 306 which will subsequently receive both the word line liner material, and a word line. As will be described in more detail below, the barrier material 422 forms a barrier layer 424 which will protect the piers and dielectric tiers during subsequent processing steps. Thus, the specific material 422 of the barrier layer 424 will be selected in accordance with the materials and associated processing mechanisms and chemistries utilized for the subsequent processing. In the present example, the barrier layer may be, for example, silicon oxide, or another material that may be selectively removed relative to the pier material.

Referring now to FIG. 4B, the figure depicts the stacked tier structure 310 after subsequent processing, in which a conformal word line liner material 426 is deposited through the pillar opening 314 and into the openings 425 defined by the barrier layer 424. Word line liner material 426 is preferably selectively removable relative to barrier layer 424, but preferably is removable with word line material 430 which will be placed next. In one example, word line material 430 may be tungsten; and the word line liner material 426 may be titanium nitride.

Once word line liner material 426 is in place, the word line material 430 is placed through the pillar openings to form word lines in within the memory tier. Subsequently, the word line material 430, as well as the word line liner material 426 will be recessed relative to the pillar openings 416 to define the word lines 432 and segments of the word line liner 428 as depicted. Such recessing may be performed through a wet etch. The described recessing in the depicted example configuration, will etch such materials away from the pillar opening, providing space for forming memory cells on opposite sides of pillar openings 314 relative to a first axis, and between other structures (in the present example, piers 420) relative to a second, generally orthogonal axis, extending in the word line direction.

Subsequently as depicted in FIG. 4C, an electrode material will be deposited through pillar openings 314, preferably extending to contact with the recessed word line material 430 (as depicted in FIG. 4C, Lateral View); and will subsequently be recessed to define first electrodes 442, each in electrical communication with a respective word line 432, on opposite sides of a respective pillar opening 314 (as depicted in FIG. 4C, Top View). These first electrodes will respectively be part of first and second memory cells, as will be described.

Subsequently, as depicted in FIG. 4D, the portion of the barrier layer 424 extending between the electrodes on opposite sides of a respective pillar opening 314 will be recessed to expose the surface 444 of at least one respective pier 420 (and in the case of the depicted example, the surfaces 444 of two piers 420 on opposite sides of a respective pillar opening 314).

Referring now to FIG. 4E, a placeholder material 450 is deposited through the pillar openings 314 and adjacent to respective first electrodes 434. Placeholder material 450 is recessed to a dimension which is desired for the storage element (in the present example, a chalcogenide memory element (452, depicted in FIG. 4H), which will be between first electrodes 434 and subsequently formed second electrodes 442, which are formed next. Material for second electrodes 454 (which in many examples will be the same material as used for first electrodes 442, is deposited through the pillar opening 314, and subsequently recessed to redefine pillar opening 314 to a desired dimension. Then, a pillar material 446, for example tungsten, which will serve as a vertically extending portion of respective bit lines of the array is deposited into the redefined pillar openings 314. As will be apparent to persons skilled in the art, in selected examples a lower portion of each pillar opening 314 extending below the stacked tier structure 310 may be filled before performing the operations described above in a relatively upper portions of each pillar opening 314, to protect layers or other structures below from the described processing. Thus, in some examples, such a lower fill material, when present, may be exhumed before depositing of the pillar material 446 through the stacked tier structure.

In the depicted example, the second electrodes 454 may be formed together as a continuous structure in electrical contact with pillar material 446, and in some cases, as depicted, the continuous structure may surround the pillar material forming the vertically extending bit line. In other examples, the second electrodes may be electrically isolated from one another. For clarity, the term “second electrodes” is maintained in the continuous structure of the present example, in view of the function of the second electrode structure in the operation of each memory cell, in which a single electrode serves the electrical function of multiple electrodes. Additionally, the pillar material 446 may be surrounded by a pillar liner (for example, a titanium nitride liner around a tungsten pillar).

Referring now to FIG. 4F, in the depicted example processing flow, a center pier of three adjacent piers along the word line direction will be exhumed to facilitate completion of the memory cells. As can be seen in the figures, the previously placed barrier material 422 prevents exposure of the word line liner material to the exhuming chemistry, and thus protects word line liner 428 from possible damage as the pier 420 is exhumed, and thereby further protects word line 432 from damage. This benefit is achieved by maintaining multiple barrier materials between the piers (and during processing, the pier openings) and a nearby portion of word lines extending near the pier (or pier opening). In the present example this result is achieved by maintaining at least a segment of each of two barrier materials (the first pier barrier material, and the word line liner material), between a respective access line and the pier and/or pier opening. This isolation assists in protecting and maintaining integrity of the word lines during the construction of the memory array. As will be described relative to subsequent features, in some examples, at least three barrier materials may be maintained in such position, at least through a portion of memory array formation.

Referring now to FIG. 4G, after exhuming the selected piers, the placeholder material 450 used when forming the spaced electrodes will be recessed (partially exhumed), forming cavities 448 between each respective first electrode 434 and respective second electrode 454 (on both sides of the pier opening 312), through the pier opening 312 vacated by exhumed pillar 446A. Such cavities will be formed to both sides of exhumed pillar 446A.

Subsequently, the chalcogenide material forming the memory element 456 is deposited in each cavity 448, adjacent the remaining placeholder material 450, and etched back to a desired dimension. Subsequently, the remaining portion of the cavities 448 between first electrodes 452 and second electrodes 454, as well as within the pier opening 312, will be filled with suitable seal material 458, for example, an oxide, to complete the memory array structure, as depicted in FIG. 4I. Once such seal material 458 is in place, the memory element is constrained in a first lateral direction between the first and second electrodes 434, 454, respectively, and in a second lateral direction between first and second spacers in cavity 448, formed by placeholder material 450 and seal material 458 in cavity 448.

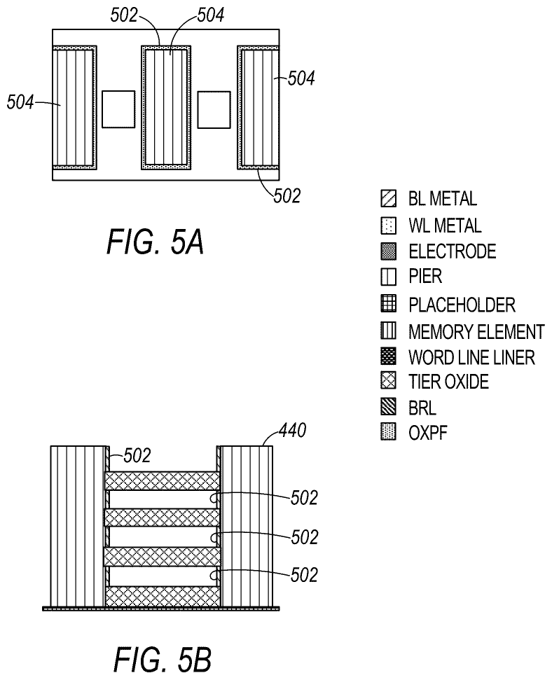

Referring now to FIGS. 5A-5B, the figures depict an alternative process flow 500 for providing protective barrier layers in an example multi-tier memory array. Process flow 500 differs from example process flow 400 primarily in that instead of the deposited barrier layer 424 discussed relative to FIG. 4A, process flow 500 forms an oxide barrier 502 at exposed surfaces of pier 420 through oxidizing exposed surfaces of the pier. Process flow 500 begins as described relative to FIG. 4A, in which initial material in the memory tiers, which may be a nitride, is exhumed in preparation for forming the replacement gates/wordlines. However, instead of depositing the barrier layer 424 on the exposed surfaces, in example process flow 500, after exhuming the initial material of the memory tiers 308 (for example, a nitride), the exposed surfaces of the pier fill material 410 forming pier 420 are oxidized to form an oxide barrier 502 at those surfaces. The oxidation may be achieved, for example, through a through a diffusion process.

One additional difference from process flow 400 is that, at least in some envisioned implementations of that process flow, and as depicted in FIG. 4A, the deposited barrier layer 424 was not only on exposed surfaces of the pier 420, but also on surfaces of the dielectric tiers 306. As will be apparent to persons skilled in the art, the oxidation of the pier fill material 410 as in process flow 500 to form the oxide barrier 502, isolates the oxide barrier 502 to the exposed surfaces of the pier fill material 410 extending through the memory tiers 308, the location of potentially greatest concern regarding potential damage to the to the word line, and/or word line liner. (see FIG. 5A, Lateral View; as compared with FIG. 4A Lateral View).

As depicted in FIG. 5B, in a manner analogous to process flow 400 a conformal word line liner material 426 is deposited through the pillar opening and into the openings in the memory tiers 308 defined by vertically neighboring dielectric tiers 306, and by the oxide barrier 502 formed on pier fill material 410 extending through the memory tiers 308. As with process flow 400, deposition of the word line liner 428 is followed by deposition of material for word line 432; and both layers are recessed. And after deposition of first electrodes 434, oxide barrier 502 extending between the formed first electrodes will be removed by etching.

All following steps proceed as described in process flow 400 to form remaining components of the memory cells, with remaining portions of oxide barrier 502 in the place of the remaining portions of barrier layer 424 of process flow 400. Accordingly, the remaining structures of the memory tier are numbered the same as in FIGS. 4A-4H, and the description of those figures applies equally to placement and partial etch back of oxide barrier 502 as discussed relative to barrier layer 424; and to the remainder of forming the structure resulting from process flow 400.

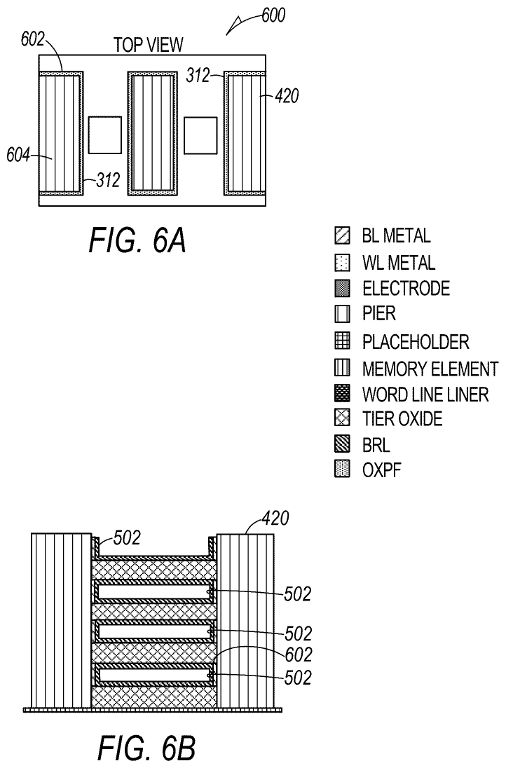

Referring now to FIGS. 6A-6B, the figures depict another alternative process flow 600, closely related in many respects to process flow 400, but differing in the timing and placement of a barrier layer 602. In alternative process flow 600 a generally conformal barrier layer 602, which may be an oxide layer, is deposited within pier openings 312 of FIG. 3B to provide a continuous and generally conformal barrier layer 602 along the surfaces defining the pier openings 312; and to then deposit pier fill material 604 within the liner. Subsequently, pillar openings (314 in FIG. 3B) may be formed, such as by dry etching, to facilitate further processing, including exhuming the nitride or other material within the memory tiers, resulting in the structure of FIG. 6B in which the piers extend within a continuous and generally conformal oxide barrier layer 602. Subsequent processing may be performed, substantially as described relative to processing flow 400, relative to FIGS. 4B-4G.

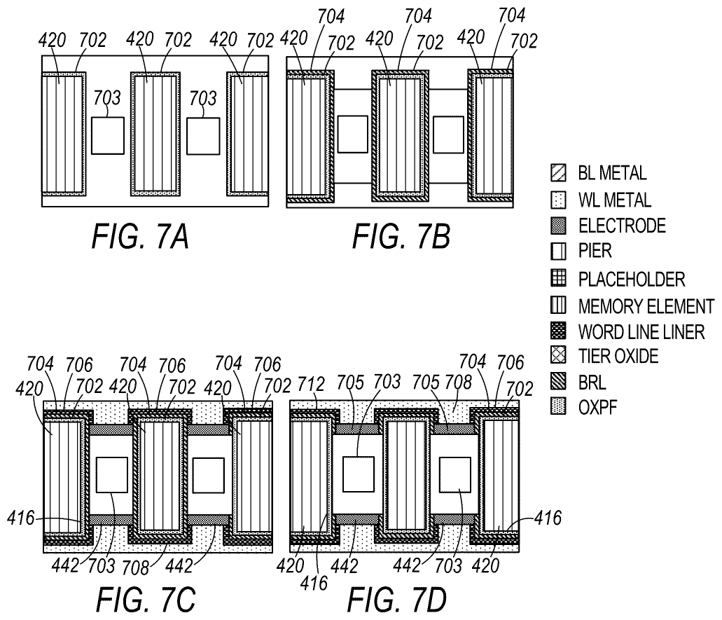

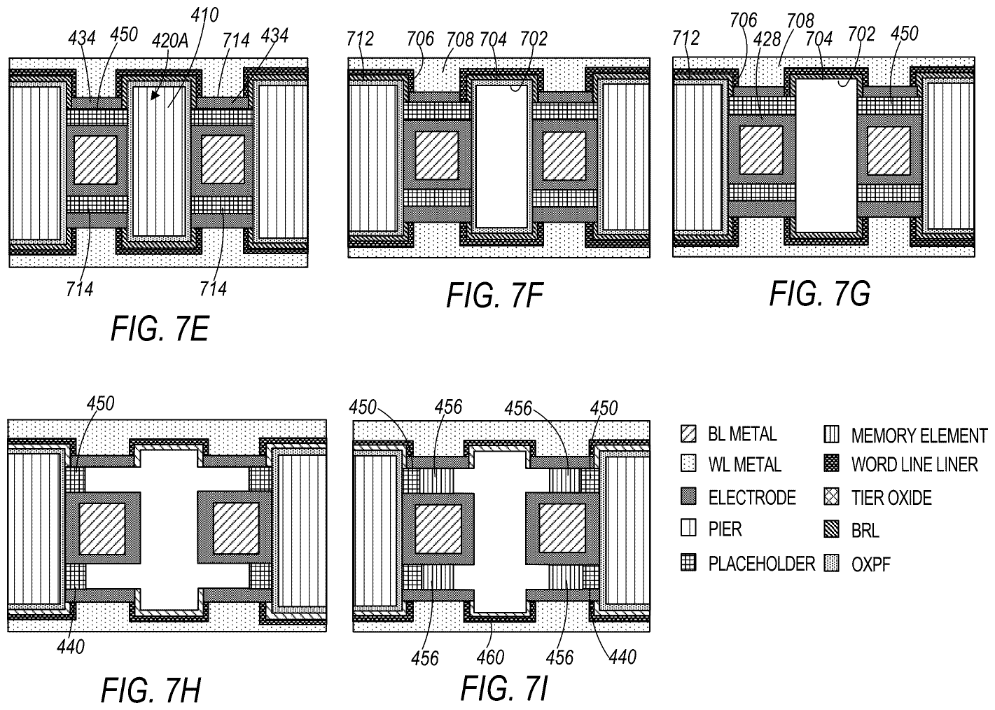

Referring now to FIGS. 7A-I, the figures depict a further alternative process flow 700 for forming the memory array which utilizes both an oxidized surface barrier 702 (such as oxide barrier 502), and a deposited barrier 704 (such as barrier layer 424) as protective materials on the piers during further processing. Process flow 700 may be used, for example, to potentially improve the protection of the word line, the word line liner, and the placeholder material during the pier exhume process by inclusion of an additional removable protective oxide layer. Because aspects of the disclosure are directly analogous to structures and operations described previously with respect to, for example, initial stages of processing flow 500, with further processing in accordance with processing flow 400 in reference to FIGS. 4C-4I, as well as FIGS. 3A-3B, those directly analogous structures will be identified with numerals from such figures.

Referring to FIG. 7A, the Figure depicts processing after exhuming of the initial material of memory tiers 308 (again, for example, nitride) as described relative to FIG. 5A. As with processing flow 500, the exposed surfaces of the pier fill material 410 are oxidized in a similar manner to form an oxide barrier 702 at exposed surfaces of the piers. In the depicted example process flow 700, the oxidized surfaces will include the sidewalls of the piers 420 extending through the vertical dimensions of the respective memory tiers, thus resulting in a structure as depicted in FIG. 5B. Subsequently, as shown in FIG. 7B, a barrier layer 704 is deposited over oxide barrier 702, and in some embodiments, also over other surfaces exposed by the exhuming of the initial material of memory tiers 308 (such as the then-exposed oxide material of the dielectric tiers 306), in a manner similar to that described relative to FIG. 4A.

Subsequently, as shown in FIG. 7C, the word line liner 706 and word line material 708 may then be deposited through the pillar openings 703, and then etched back (In a manner previously described relative to FIG. 4B). Once the word line material 708 and word line liner 706 have been etched back to define a recess in which memory cell structures will be formed, electrode material 705 is deposited and etched back to a desired location. Subsequently, barrier layer 704 may be etched back, for example approximately to the exposed surface of electrode material 705, leaving segments 712 of barrier layer 704 intact at the ends of the piers, as depicted in FIG. 7D. These barrier layer 704 segments 712 will protect the word line stack at the ends of the piers from later processing chemistries, such as those used for recessing the placeholder material from alternate piers 720A (see FIG. 7E), before placement of the memory material (716 in FIG. 7I).

In the manner described previously relative to processing flow 400 Electrode material will be deposited through pillar openings 416, and subsequently recessed to define first electrodes 434, each in electrical communication with a respective word line 432, on opposite sides of a respective pillar opening 416. As best seen in FIG. 4D, the barrier layer 424 will be recessed to expose the pier surface 436, extending between the electrodes 434.

A placeholder material 440 is deposited through the pillar openings and adjacent to first electrodes 434, and recessed to a lateral dimension which is desired for the chalcogenide memory element (450, depicted in FIG. 4H) between first electrodes 434 and subsequently formed second electrodes 442, which are formed next. Again, material for second electrodes 442 (which in many examples will be the same material as used for first electrodes 434, in the present example carbon), is deposited through the pillar opening 416, and subsequently recessed to redefine pillar opening 416 to a desired dimension. Then, a pillar material 446, for example tungsten, which will serve as a vertically extending portion of respective bit lines of the array is deposited into the redefined pillar openings 416.

As will be apparent to persons skilled in the art, in some implementations, a lower portion of each pillar opening 416 extending below the stacked tier structure may be filled before performing the operations described above, so as to protect layers or other structures below from the described processing. Thus, in some examples, such a lower fill material, when present, may be exhumed before depositing of the pillar material 446 through the stacked tier structure.

Referring now to FIG. 7F, processing flow 700 includes exhuming alternate piers 420A along the word line direction, to facilitate completion of the memory cells. In processing flow 700, the un-oxidized pier fill material 410 may be selectively removed relative to the oxide barrier 702. For example, where the pier fill material 410 is silicon nitride; the un-oxidized pier fill material 410 may be selectively removed relative to oxide barrier 702 by a wet etch. This facilitates oxide barrier 702 providing a barrier to damage of word line liner 428 and placeholder material 450 during exhuming of the alternate piers. After exhuming of the alternate piers, the oxide barrier 702 may be exhumed, with segments of oxide barrier 702 protecting word line liner 428, thus avoiding damage to word line 432 during the exhumation.

The memory cell may be constructed in a manner directly analogous to that of process flow 400, in which the placeholder material 450 and memory element 456 will be formed in a manner analogous to that described relative to FIGS. 4G-4I, and the corresponding elements are identified by the numbers of FIGS. 4A-4I.

After exhuming the alternate piers, the placeholder material 450 used when defining the memory cell will be recessed, providing a cavity 448 between each respective first electrode 434 and a respective second electrode 442, on both sides of the pillar material 446, and to both sides of the exhumed pier. Subsequently, the chalcogenide material forming the memory element 456 is deposited in each cavity 448 and adjacent the remaining placeholder material 450. Subsequently, the remaining portion of the cavity 448 between first electrodes 434 and second electrodes 442, as well as within the pier opening, will be filled with suitable seal material, for example an oxide (or other dielectric materials that are not reactive to the memory cell material), to complete the three-dimensional memory array.

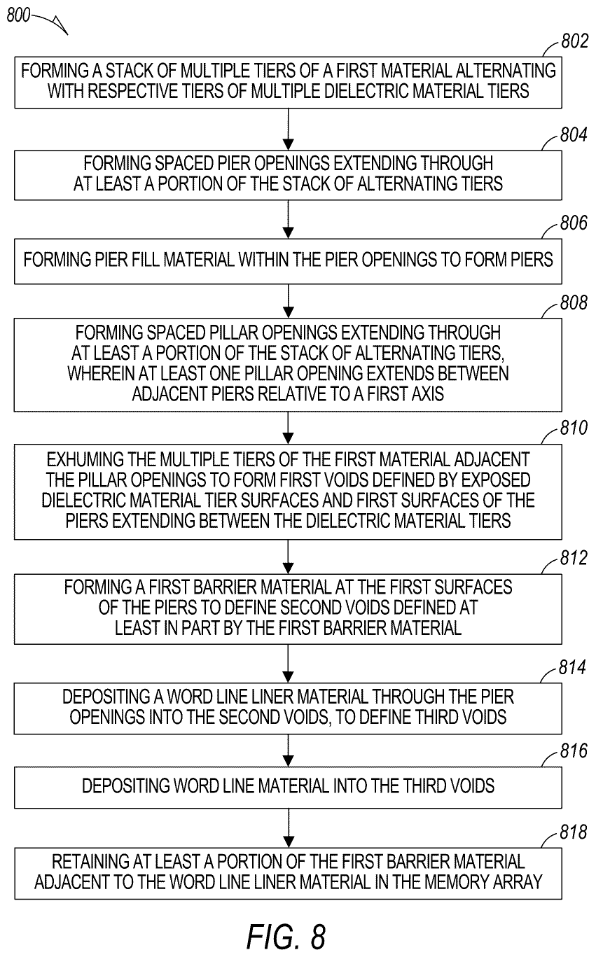

Referring now to FIG. 8, the figure depicts an example flow chart of a method 800 for constructing a 3D cross-point memory array having vertically extending piers and pillars extending through a stacked tier structure, and which may be implemented to form multiple material barriers protecting conductive structures, such as word lines, during processing operations.

Example method 800 begins with forming the stacked tier structure 802, wherein the stack includes multiple tiers of a first material (308 in FIG. 3A) alternating with respective tiers of multiple dielectric material tiers (306 in FIG. 3A) that will be used in forming a memory array, as described relative to FIGS. 3A and 3B. As described relative to such figures, the stacked tiers 308, 306 may be formed over a substrate (304 in FIG. 3A), and potentially over multiple conductive and non-conductive materials located between the stacked tiers and the substrate. Subsequently, as indicated at 804, spaced pier openings (312 in FIG. 3B) will be formed extending through at least a portion of the stack of alternating tiers; and as indicated at 806, pier fill material 410 will be formed within the pier openings (312) to form vertically extending piers (420 in FIG. 4A).

Additionally, as indicated at 808, spaced pillar openings (314 in FIG. 3B) will be formed extending through at least a portion of the stack of alternating tiers. In selected embodiments, such as the example embodiment described herein, the spaced pillar openings (314) may be located between adjacent piers (or pier openings) relative to a first axis. For the avoidance of doubt, operation 806 of forming pier fill material 410 within the pier openings (312) may be performed before or after forming of the pillar openings (314).

As indicated at 810, the example method 800 includes exhuming the multiple tiers of the first material, either completely, or at least adjacent the pillar openings (314), to define voids defined by exposed dielectric material tier surfaces and first surfaces of the piers extending between the dielectric material tiers. Subsequent, as indicated in 812, the method includes forming a first barrier material at the first surfaces of the piers, to have the effect of defining second voids defined at least in part by the first barrier material. As will be apparent from the preceding discussion, the first barrier material made to be deposited, such as barrier layer 424 in example process flow 400; or alternatively may be formed by oxidizing the first surfaces of the piers extending between the dielectric material tiers, such as oxide 50X in example process flow 500. Additionally, example method 800 is not limited to a single barrier material, and multiple barrier materials may be deposited proximate one another. Or, alternatively, as described relative to example process flow 600, one barrier material may be formed by oxidation of an existing surface, and an additional barrier material may be formed by deposition.

As indicated in 814, the example method 800 includes depositing a word line liner material through the pier openings and into the second voids defined at least in part by the first barrier material, which will have the practical effect of defining third voids, into which word line material will be deposited, as indicated at 816. As a result, the first barrier material may be used to protect the word line liner, and word line, during subsequent operations in forming the memory array.

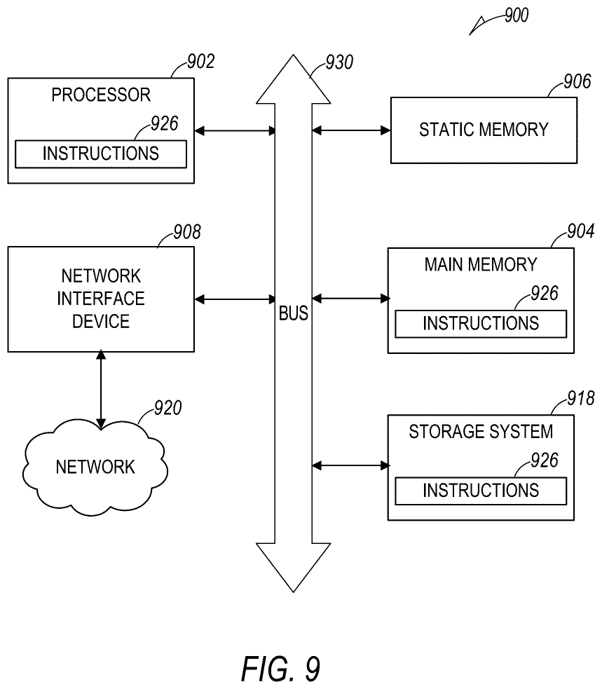

FIG. 9 illustrates a block diagram of an example electronic machine (e.g., a host system) 900 which may include one or more memory devices and/or systems as described above. A cross-point memory structure as previously described herein may be implemented as a discrete memory device, as a portion of a multi-chip device, or as a memory array formed on a device with other logic. For example, the cross-point memory structure as described herein could be implemented as first-tier cache memory or as a buffer available to a processor, and could potentially be formed on a common substrate with processing circuitry. The described cross-point memory structure may be used for any memory application within electronic machine 900. Machine 900 may benefit from enhanced memory reliability and/or performance from use of one or more of the described memory devices and/or memory systems, facilitating improved performance of machine 9000 (as for many such machines or systems, efficient reading and writing of memory can facilitate improved performance of a processor or other components that machine, as described further below).

In alternative embodiments, the machine 900 may operate as a standalone device or may be connected (e.g., networked) to other machines. In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 900 may include a processing device 902 (e.g., a hardware processor, a central processing unit (CPU), a graphics processing unit (GPU), a hardware processor core, or any combination thereof, etc.), a main memory 904 (e.g., read-only memory (ROM), dynamic random-access memory (DRAM) such as synchronous DRAM (SDRAM) or Rambus DRAM (RDRAM), etc.), a static memory 906 (e.g., static random-access memory (SRAM), etc.), and a storage system 918, some or all of which may communicate with each other via a communication interface (e.g., a bus) 930. In one example, the main memory 904 or the storage system 918 may include one or more memory devices as described in examples above.

The processing device 902 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 902 can also be one or more special-purpose processing devices such as an application specific integrated circuit (ASIC), a field programmable gate array (FPGA), a digital signal processor (DSP), network processor, or the like. The processing device 902 can be configured to execute instructions 926 for performing the operations and steps discussed herein. The processing device 902 can further include a network interface device 908 to communicate over a network 920.

The storage system 918 can include a machine-readable storage medium (also known as a computer-readable medium) on which is stored one or more sets of instructions 926 or software embodying any one or more of the methodologies or functions described herein. The instructions 926 can also reside, completely or at least partially, within the main memory 904 or within the processing device 902 during execution thereof by the computer system 900, the main memory 904 and the processing device 902 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 900 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 900 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 926 (e.g., software, programs, an operating system (OS), etc.) or other data are stored on the storage system 918 can be accessed by the main memory 904 for use by the processing device 902. The main memory 904 (e.g., DRAM) is typically fast, but volatile, and thus a different type of storage than the storage system 918 (e.g., an SSD), which is suitable for long-term storage, including while in an “off” condition. The instructions 926 or data in use by a user or the machine 900 are typically loaded in the main memory 904 for use by the processing device 902. When the main memory 904 is full, virtual space from the storage system 918 can be allocated to supplement the main memory 904; however, because the storage system 918 device is typically slower than the main memory 904, and write speeds are typically at least twice as slow as read speeds, use of virtual memory can greatly reduce user experience due to storage system latency (in contrast to the main memory 904, e.g., DRAM). Further, use of the storage system 918 for virtual memory can greatly reduce the usable lifespan of the storage system 918.

The instructions 924 may further be transmitted or received over a network 920 using a transmission medium via the network interface device 908 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.9 family of standards known as Wi-Fi®, IEEE 802.16 family of standards known as WiMax®), IEEE 802.15.4 family of standards, pier-to-pier (P2P) networks, among others. In an example, the network interface device 908 may include one or more physical jacks (e.g., Ethernet, coaxial, or phone jacks) or one or more antennas to connect to the network 920. In an example, the network interface device 908 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 900, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” and “substrate” are used herein to refer generally to any structure on which integrated circuits are formed, and also to such structures during various stages of integrated circuit fabrication. The following detailed description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells. As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

As used herein, directional adjectives, such as horizontal, vertical, normal, parallel, perpendicular, etc., can refer to relative orientations, and are not intended to require strict adherence to specific geometric properties, unless otherwise noted. For example, as used herein, a vertical structure need not be strictly perpendicular to a surface of a substrate, but may instead be generally perpendicular to the surface of the substrate, and may form an acute angle with the surface of the substrate (e.g., between 60 and 120 degrees, etc.).

Operating a memory cell, as used herein, includes reading from, writing to, or erasing the memory cell. The operation of placing a memory cell in an intended state is referred to herein as “programming,” and can include both writing to or erasing from the memory cell (i.e., the memory cell may be programmed to an erased state).

According to one or more embodiments of the present disclosure, a memory controller (e.g., a processor, controller, firmware, etc.) located internal or external to a memory device, is capable of determining (e.g., selecting, setting, adjusting, computing, changing, clearing, communicating, adapting, deriving, defining, utilizing, modifying, applying, etc.) a quantity of wear cycles, or a wear state (e.g., recording wear cycles, counting operations of the memory device as they occur, tracking the operations of the memory device it initiates, evaluating the memory device characteristics corresponding to a wear state, etc.)

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of Examples is provided:

Example 1 is a method of forming a memory structure, comprising: forming a stack of multiple tiers of a first material alternating with respective tiers of multiple dielectric material tiers; forming spaced pier openings extending through at least a portion of the stack of alternating tiers; forming pier fill material within the pier openings to form piers; forming spaced pillar openings extending through at least a portion of the stack of alternating tiers, wherein at least one pillar opening extends between adjacent piers relative to a first axis; exhuming the multiple tiers of the first material adjacent the pillar openings to form first voids defined by exposed dielectric material tier surfaces and first surfaces of the piers extending between the dielectric material tiers; forming a first barrier material on the first surfaces of the piers to form second voids defined at least in part by the first barrier material; depositing a word line liner material through the pier openings into the second voids, to define third voids; and depositing word line material into the third voids.

In Example 2, the subject matter of Example 1 wherein the first barrier material is a deposited barrier material, and wherein the first barrier material is further deposited on exposed dielectric material tier surfaces to further define the second voids.

In Example 3, the subject matter of Example 2 wherein the first barrier material comprises oxide.

In Example 4, the subject matter of any one or more of Examples 1-3 wherein the first barrier material is an oxide formed by oxidizing exposed portions of the pier fill material.

In Example 5, the subject matter of Example 4 wherein the first barrier material comprises the oxide formed by oxidizing exposed portions of the pier fill material, and wherein the method further comprises depositing a supplemental barrier material over at least a portion of the oxidized pier fill material.

In Example 6, the subject matter of any one or more of Examples 1-5 optionally include recessing the word line liner material and the word line material.

In Example 7, the subject matter of Example 6 wherein the word line material is isolated from the pier fill material by at least the first barrier material.

In Example 8, the subject matter of any one or more of Examples 6-7 wherein both the word line liner material and the word line material are deposited, and then recessed, wherein the word line material is isolated from the pier fill material by both the first barrier material and the word line liner material.

In Example 9, the subject matter of any one or more of Examples 6-8 optionally include forming multiple memory cell units comprising at least two variable resistance memory cells on opposite sides of a respective pillar opening, and between adjacent piers; wherein each variable resistance memory cell comprises a first electrode, a variable resistance material, and a second electrode; wherein the first electrodes are in electrical communication with respective word lines; and wherein the second electrodes are each in electrical communication with bit line material extending through a respective pillar opening.

In Example 10, the subject matter of Example 9 wherein the second electrodes of memory cells in a memory cell unit are integral with one another.

In Example 11, the subject matter of any one or more of Examples 9-10 wherein the variable resistance material of each memory cell is constrained in a first direction between the first and second electrodes, and in a second direction between first and second spacers.

In Example 12, the subject matter of Example 11 wherein forming the multiple memory cell units comprises: forming the first electrodes in contact with respective word lines, and extending between the first barrier material on adjacent piers; forming the second electrodes of each memory cell in electrical communication with the bit line material extending through the pillar openings; forming first spacers extending between the first and second electrodes for the memory cells; forming the variable resistance material adjacent the respective spacers, and between the respective first and second electrodes; and forming respective second spacers between the first and second electrodes for the memory cells.

In Example 13, the subject matter of Example 12 optionally includes after forming the first electrodes of each memory cell, recessing the pier barrier material on the adjacent piers to a location of the first electrodes.

In Example 14, the subject matter of any one or more of Examples 12-13 optionally includes depositing first electrode material laterally between adjacent piers, the first electrode material in contact with the first barrier material on the adjacent piers and the word line material; recessing the electrode material, leaving a portion of the first barrier material exposed; and removing the exposed first barrier material from the adjacent piers.

In Example 15, the subject matter of Example 14 optionally includes forming spacer material extending between contacts with adjacent piers; forming the second electrodes surrounding a pillar opening between two adjacent piers; and forming bit line material within the respective pillar opening.

In Example 16, the subject matter of any one or more of Examples 14-15 optionally includes removing a center pier of three adjacent piers relative to a first axis; through a center pier opening created by removing the center pier, recessing the spacer material between the first and second electrodes in memory cell units to either side of the center pier opening relative to the first axis; forming a variable resistance material element adjacent the respective recessed spacer materials, and in contact with the first and second electrodes; and forming a dielectric material extending within the center pier opening and further in contact with the variable resistance material element between the first and second electrodes.

Example 17 is a memory cell structure, comprising: a stack of memory tiers, respectively containing multiple crosspoint memory cells, and alternate dielectric tiers between the memory tiers; multiple word lines which extend to a first plurality of memory cells in a memory tier; and multiple bit lines which extend at least in part generally orthogonally to the multiple word lines, and which extends to a second plurality of memory cells distributed across multiple memory tiers; wherein the stack of memory tiers and dielectric tiers includes piers which extend through multiple memory tiers and dielectric tiers, and which are isolated from contact with respective word lines, by at least a first barrier material extending laterally between the piers and the respective word lines.

In Example 18, the subject matter of Example 17 optionally includes a word line liner material also extending laterally between the piers and the respective word lines.

In Example 19, the subject matter of any one or more of Examples 17-18 wherein the first barrier material also extends between the word lines and the dielectric tiers.

In Example 20, the subject matter of any one or more of Examples 17-19 wherein the first barrier material comprises an oxide.

In Example 21, the subject matter of any one or more of Examples 18-20 wherein the first barrier material is an oxide formed by oxidizing exposed surfaces of the piers.

In Example 22, the subject matter of any one or more of Examples 17-21 optionally include a second barrier material adjacent the first barrier material, wherein the second barrier material comprises oxidized pier fill material, and wherein the first barrier material is deposited over the second barrier material.

In Example 23, the subject matter of any one or more of Examples 17-22 wherein the first barrier material is selectively removable relative to the second barrier material.

Example 24 is a method of forming a memory structure, comprising: forming a stack of multiple tiers of a first material alternating with respective tiers of multiple dielectric material tiers; forming spaced pier openings extending through at least a portion of the stack of alternating tiers; forming a first barrier lining material within the pier openings; depositing pier fill material within the pier openings to form piers; forming spaced pillar openings extending through at least a portion of the stack of alternating tiers, wherein at least one pillar opening extends between adjacent piers relative to a first generally horizontal axis; exhuming the multiple tiers of the first material adjacent the pillar openings to form first voids defined by exposed dielectric material tier surfaces, and exposed first barrier liner material extending between the dielectric material tiers; depositing a word line liner material and word line material through the pillar openings into the first voids; and recessing both to define the word lines and word line liner; forming first electrodes extending between adjacent piers and respective portions of first barrier lining material, and subsequently etching exposed first barrier liner material to expose a surface of the piers; through the pillar openings, forming second electrodes of respective memory cells, the second electrodes in spaced relation to the first electrodes established through by a placeholder material; forming vertically extending conductive pillars within the pillar openings the conductive pillars in electrical communication with one or more adjacent second electrodes; exhuming a central pier of three adjacent piers along the first generally horizontal axis to leave a pier opening containing a remaining portion of the first barrier liner as a barrier to exposure of the word line liner material to exhuming chemistry; and through the pier openings, removing a portion of the placeholder material between the first and second electrodes to define recesses, and forming variable resistance memory elements in the recesses the variable resistance memory elements in electrical communication with respective first and second electrodes.

In Example 25, the subject matter of Example 24 wherein at least two second electrodes of respective memory cells are formed adjacent a respective bit line.

In Example 26, the subject matter of any one or more of Examples 24-25 wherein the at least two second electrodes are formed as a single structure at least partially surrounding the respective bit line.

In Example 27, the subject matter of any one or more of Examples 24-26 wherein forming first barrier lining material within the pier openings comprises depositing a first barrier lining material through the pillar openings.

Example 28 is a three-dimensional cross-point memory structure, comprising: a memory array comprising, multiple memory tiers stacked in alternating relation with multiple dielectric tiers, the memory tiers respectively comprising multiple memory cells, and multiple conductive access lines extending to respective memory cells within the respective tier; multiple piers extending vertically through at least a portion of the stacked memory and dielectric tiers; multiple barrier materials extending between each respective pier and a portion of an access line extending horizontally within a memory tier and adjacent such piers.

In Example 29, the subject matter of Example 28 wherein the access line is a word line; wherein a first of the multiple barrier materials is a word line liner, extending in contact with an adjacent word line; and wherein a second of the multiple barrier materials is in contact with an adjacent pier.

In Example 30, the subject matter of Example 29 wherein the memory array further comprises multiple conductive pillars extending vertically through the stacked memory and dielectric tiers; and wherein each memory cell comprises a memory element in electrical communication with a respective conductive pillar and a respective word line.

In Example 31, the subject matter of Example 30 wherein the second of the multiple barrier materials extends adjacent an associated pier through multiple memory tiers.

In Example 32, the methods of any of Examples 1-16 or 24-27 may be implemented formed structures, or portions thereof, of any of Examples 17-23 or 28-31.

In Example 33 any of the operations described in any of Examples 1-16 may be implemented as a portion of Examples 24-27.

In Example 34, any of the operations described in any of Examples 24-37 may be implemented as a portion of Examples 1-16.

In Example 34, the structures of any of Examples 17-23 or 28-31 may be made through operations forming a part of any of Examples 1-16 or 24-27.

The above description is intended to be illustrative, and not restrictive. For Example, the above-described Examples (or one or more aspects thereof) may be used in combination with each other. Other embodiments can be used, such as by one of ordinary skill in the art upon reviewing the above description. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A method of forming a memory structure, comprising:
forming a stack of multiple tiers of a first material alternating with respective tiers of multiple dielectric material tiers;
forming spaced pier openings extending through at least a portion of the stack of alternating tiers;
forming pier fill material within the pier openings to form piers;
forming spaced pillar openings extending through at least a portion of the stack of alternating tiers, wherein at least one pillar opening extends between adjacent piers relative to a first axis;
exhuming the multiple tiers of the first material adjacent the pillar openings to form first voids defined by exposed dielectric material tier surfaces and first surfaces of the piers extending between the dielectric material tiers;
forming a first barrier material on the first surfaces of the piers to form second voids defined at least in part by the first barrier material;
depositing a word line liner material through the pier openings into the second voids, to define third voids; and
depositing word line material into the third voids.

2. The method of forming a memory structure of claim 1, wherein the first barrier material is a deposited barrier material, and wherein the first barrier material is further deposited on exposed dielectric material tier surfaces to further define the second voids.

3. The method of forming a memory structure of claim 2 wherein the first barrier material comprises oxide.

4. The method of forming a memory structure of claim 1, wherein the first barrier material is an oxide formed by oxidizing exposed portions of the pier fill material.

5. The method of forming a memory structure of claim 4, wherein the first barrier material comprises the oxide formed by oxidizing exposed portions of the pier fill material, and wherein the method further comprises depositing a supplemental barrier material over at least a portion of the oxidized pier fill material.

6. The method of forming a memory structure of claim 1, wherein the word line material is isolated from the pier fill material by at least the first barrier material.

7. The method of forming a memory structure of claim 1, wherein both the word line liner material and the word line material are deposited, and then recessed, wherein the word line material is isolated from the pier fill material by both the first barrier material and the word line liner material.

8. The method of forming a memory structure of claim 1, comprising:
forming multiple memory cell units comprising at least two variable resistance memory cells on opposite sides of a respective pillar opening, and between adjacent piers;
wherein each variable resistance memory cell comprises a first electrode, a variable resistance material, and a second electrode;
wherein the first electrodes are in electrical communication with respective word lines; and
wherein the second electrodes are each in electrical communication with bit line material extending through a respective pillar opening.

9. The method of forming a memory structure of claim 8, wherein the second electrodes of memory cells in a memory cell unit are integral with one another.

10. The method of forming a memory structure of claim 8, wherein the variable resistance material of each memory cell is constrained in a first direction between the first and second electrodes, and in a second direction between first and second spacers.

11. The method of forming a memory structure of claim 10, wherein forming the multiple memory cell units comprises:
forming the first electrodes in contact with respective word lines, and extending between the first barrier material on adjacent piers;
forming the second electrodes of each memory cell in electrical communication with the bit line material extending through the pillar openings;
forming first spacers extending between the first and second electrodes for the memory cells;
forming the variable resistance material adjacent the respective spacers, and between the respective first and second electrodes; and
forming respective second spacers between the first and second electrodes for the memory cells.

12. The method of forming a memory structure of claim 11, further comprising:
depositing first electrode material laterally between adjacent piers, the first electrode material in contact with the first barrier material on the adjacent piers and the word line material;
recessing the electrode material, leaving a portion of the first barrier material exposed; and
removing the exposed first barrier material from the adjacent piers.

13. The method of forming a memory structure of claim 12, further comprising:
forming spacer material extending between contacts with adjacent piers;
forming the second electrodes surrounding a pillar opening between two adjacent piers; and
forming bit line material within the respective pillar opening.

14. The method of forming a memory structure of claim 12, comprising:
removing a center pier of three adjacent piers relative to a first axis;
through a center pier opening created by removing the center pier, recessing the spacer material between the first and second electrodes in memory cell units to either side of the center pier opening relative to the first axis;
forming variable resistance material elements adjacent the respective recessed spacer materials, and in contact with the first and second electrodes; and
forming a dielectric material extending within the center pier opening and further in contact with the variable resistance material element between the first and second electrodes.

15. A memory cell structure, comprising:
a stack of memory tiers, respectively containing multiple crosspoint memory cells, and alternate dielectric tiers between the memory tiers;
multiple word lines which extend to a first plurality of memory cells in a memory tier; and
multiple bit lines which extend at least in part generally orthogonally to the multiple word lines, and which extends to a second plurality of memory cells distributed across multiple memory tiers;
wherein the stack of memory tiers and dielectric tiers includes piers which extend through multiple memory tiers and dielectric tiers, and which are isolated from contact with respective word lines, by at least a first barrier material extending laterally between the piers and the respective word lines.

16. The memory cell structure of claim 15, further comprising, a word line liner material also extending laterally between the piers and the respective word lines.

17. The memory cell structure of claim 15, wherein the first barrier material also extends between the word lines and the dielectric tiers.

18. The memory cell structure of claim 15, wherein the first barrier material comprises an oxide.

19. The memory cell structure of claim 15, further comprising a second barrier material adjacent the first barrier material, wherein the second barrier material comprises oxidized pier fill material, and wherein the first barrier material is deposited over the second barrier material.

20. The memory cell structure of claim 15, wherein the first barrier material is selectively removable relative to the second barrier material.
